(19) United States
(12) Patent Application Publication
(10) Pub. No.: US 2008/0048746 A1
(43) Pub. Date: Feb. 28, 2008

(54) Hysteresis Comparator with Programmable Hysteresis Width

(75) Inventor: Murugesan Raman, Bangalore (IN)

Correspondence Address: BAKER BOTTS, LLP, 910 LOUISIANA, HOUSTON, TX, 77002-4995, US

(73) Assignee: Microchip Technology Incorporated, Chandler, AZ (US)

(21) Appl. No.: 11/467,252

(22) Filed: Aug. 25, 2006

(51) Int. Cl. H03K 5/22

(52) U.S. Cl. 327/205; 327/77

(57) ABSTRACT

A digitally programmable hysteresis comparator a includes digitally programmable variable resistor. One or more control bits are operable to modify the resistance of the variable resistor, and such modification is operable to modify the hysteresis width of the comparator.

### TECHNICAL FIELD

The present disclosure relates generally to implementing a comparator, and more particularly to a system and a method for implementing digitally programmable hysteresis in a comparator.

### BACKGROUND

It is common to use voltage comparators (or simply “comparators”) in numerous applications within microprocessors, microcontrollers, integrated circuits and other electronic components and circuits. For example, comparators are used in various phases of signal generation and transmission, as well as in automatic control and measurement. Comparators appear both alone and as part of more complex circuits and devices, such as analog-to-digital converters, switching regulators, function generators, voltage-to-frequency converters, power-supply supervisors, uninterruptible power supplies, switch mode power supplies, level detectors, window detectors, pulse-width modulators, Schmitt triggers, motors and a variety of others.

A symbol for an ideal voltage comparator 10, as is known in the art, is depicted in FIG. 1. Voltage comparator 10 may be used as a stand-alone circuit or may used within a microprocessor, microcontroller, integrated circuit or any other suitable electronic component or circuit. The function of a comparator is to compare the voltage v_{P} at one of its inputs (positive input 6) against the voltage vₙ at the other (negative input 8), and output either a low voltage V_{OL} or a high voltage V_{OL} to output 4 according to:

v_{O}=V_{OL} for v_{P}<v_{N}

v_{O}=V_{OH} for v_{P}>v_{N}

Introducing a differential input voltage v_{D}=v_{P}−v_{N}, the above equations may alternatively be expressed as v_{O}=V_{OL} for V_{D}<0 V, and v_{O}=V_{OH} for V_{D}>0 V. The voltage transfer curve (VTC) for ideal voltage comparator 10 is depicted in FIG. 2. For non-zero values of v_{O}, the VTC consists of two horizontal lines positioned at v_{O}=V_{OL} and v_{O}=V_{OH}.

In FIG. 1, the voltage at positive input 6 is supplied by voltage source 12 with a voltage of v_{I} and the voltage at negative input 8 is supplied by a voltage source 13 with a voltage of v_{REF}. The voltage at which v_{I}=v_{REF} is known as the threshold voltage. It should be evident that in the embodiment shown in FIG. 1, v_{P}=v_{I} and v_{N}=V_{REF}. Hence, for values of v_{I}<v_{REF}, v_{O}=V_{OL}, and for values of V_{I}>v_{REF}, v_{O}=V_{OL}.

In addition to the other applications for comparators cited in this application, comparators may also be used as level or threshold detectors. Level detection can be applied to any parameter that can be expressed in terms of a voltage via a suitable transducer. Typical examples are temperature, pressure, strain, position, fluidic level, and light or sound intensity. Moreover, a comparator can be used not only to monitor a parameter, but also to control it. For example, a comparator may be used as part a temperature controller, or thermostat. In one embodiment of a thermostat, a user may set a desired temperature. Control circuitry within the thermostat may transduce a voltage (for example, a voltage VREF) corresponding to the desired temperature onto negative input 8 of voltage comparator 10. Likewise, a temperature sensor may transduce a voltage (for example, a voltage v_{I}) corresponding to the ambient temperature onto positive input 6 of voltage comparator 10. Furthermore, a cooling apparatus such as an air conditioner (or, alternatively, a heating apparatus such as a heater) may be coupled to output 4, with v_{O}=V_{OL} signaling that the air conditioner shall be “off,” and v_{O}=V_{OH} signaling that the air conditioner shall be “on.”

The example thermostat operates as follows. As long as the ambient temperature is below the desired temperature, v_{REF}>V_{I}, v_{N}>v_{P} and v_{O}=V_{OL}, and the air conditioner remains off. If, however, the ambient temperature rises above the desired temperature, then v_{REF}>V_{I}, v_{N}>v_{P} and v_{O}=V_{OH}, and the thermostat turns the air conditioner on. One skilled in the art would recognize that analogous techniques may be used to implement other level detectors and controllers such as pressure, strain, position, fluidic level, and light or sound intensity controllers, as well as other applications using comparators, such as analog-to-digital converters, switching regulators, function generators, voltage-to-frequency converters, power-supply supervisors, window detectors, pulse-width modulators, Schmitt triggers, and a variety of others.

In many applications, it is not desirable not to have an output voltage v_{O} transition from V_{OL} to V_{OH} and from V_{OH} to V_{OL} at the same threshold voltage v_{I}=v_{REF}. For example, when processing slowly varying input signals, comparators tend to produce multiple output transitions, or bounces, as the input crosses the threshold region. Known as “comparator chatter,” these bounces may often be caused by numerous factors, including AC noise invariably superimposed on the input signal, especially in industrial environments. An example of comparator chatter is shown in sample waveforms for v_{I} and v_{O} shown in FIG. 5a. As v_{I} momentarily falls below and then momentarily rises above v_{REF}, v_{O} quickly spikes from V_{OH} to V_{OL}, then back to V_{OH} again. Comparator chatter is unacceptable in a number of applications, including those involving counters.

In other applications, the existence of only one threshold voltage for both the rising and falling transitions of v_{O} may lead to excessive and unnecessary cycling of pumps, furnaces, air conditioners or motors. Consider, for instance, the thermostat discussed above. Starting with ambient temperatures above the desired temperature, the comparator will activate the air conditioner and cause temperatures to fall. This fall is monitored by the temperature sensor and conveyed to the comparator in the form of an decreasing voltage. As soon as the ambient temperature reaches the desired temperature, the comparator will trip and shut off the air conditioner. However, the smallest temperature rise following the shutting off of the air conditioner will cause the comparator to trip and turn on the air conditioner. As a result, the air conditioner will be cycled on and off at a rapid pace, which may adversely affect the longevity of components within the air conditioner due to the continuous cycling.

One method used to eliminate comparator chatter and the problem of frequent cycling in comparator circuits is hysteresis. With hysteresis, as soon as v_{I} crosses a threshold, v_{O} transitions and the hysteresis circuit activates another threshold, such that v_{I} must swing back to the new threshold in order to cause v_{O} to transition again. FIG. 3 depicts an example hysteresis comparator circuit 11 utilizing hysteresis in connection with voltage comparator 10. Hysteresis comparator circuit 11 may be used as a stand-alone circuit or may used within a microprocessor, microcontroller, integrated circuit or any other suitable electronic component or circuit. Those skilled in the art would appreciate that many other circuit configurations analogous to that depicted in FIG. 3 may be used to utilize hysteresis. A discussion of the circuit behavior of hysteresis comparator circuit 11 may be better understood with reference to FIG. 4, which depicts a VTC for hysteresis comparator circuit 11.

As those skilled in the art would appreciate, output 4 has two stable states, and hence the circuit has two possible values for the threshold voltage of input voltage v_{I}, namely:

$${V}_{TH} = ( \frac{{R}_{A}}{{R}_{B}} + 1 ) {V}_{REF} - \frac{{R}_{A}}{{R}_{B}} {V}_{OL}$$

$${V}_{TL} = ( \frac{{R}_{A}}{{R}_{B}} + 1 ) {V}_{REF} - \frac{{R}_{A}}{{R}_{B}} {V}_{OH}$$

For v_{I}<<0, v_{O} saturates at v_{O}=V_{OH}. Increasing v_{I} moves the operating point along the lower segment of the VTC until v_{I} reaches V_{TH}. At this junction, the regenerative action of positive feedback causes v_{O} to snap from V_{OL} to V_{OH}. This in turn causes the threshold v_{I} needed to switch v_{O} from V_{OH} to V_{OL} to drop to V_{TL}. Hence, if the output is to change state again, v_{I} must be lowered back down to v_{I}=V_{TL}. Hence, we observe that when coming from the left, the threshold is V_{TH}, and when coming from the right, it is V_{TL}. This can also be appreciated from the waveforms of FIG. 5b, where it is seen that during the times of increasing v_{I} the output snaps when v_{I} crosses V_{TH}, but during times of decreasing v_{I} it snaps when v_{I} crosses V_{TL}.

The “hysteresis width” of hysteresis comparator circuit 11 may be defined as ΔV_{T}=V_{TH}−V_{TL}, which can also be expressed as:

If desired, the hysteresis width for a particular hysteresis comparator circuit, such

$$Δ {V}_{T} = \frac{{R}_{A}}{{R}_{B}} ( {V}_{OH} - {V}_{OL} )$$

as hysteresis comparator circuit 1, can be set by selecting appropriate component values for the bias resistors, such as resistor 16 (R_{A}) and resistor 18 (R_{B}). In the depicted embodiment, increasing the ratio R_{A}/R_{B} increases the hysteresis width while decreasing the ratio R_{A}/R_{B} decreases the hysteresis width. Analogous methods may be used to set the hysteresis width in other implementations of hysteresis comparator circuits. In many cases, it is desirable to provide a mechanism to vary the resistances of bias resistors within a hysteresis comparator circuit—in other words, a mechanism to “program” hysteresis width—thus allowing greater control over hysteresis width. Such programmability would allow a user the ability to fine tune to the hysteresis width of a comparator in accordance with the particular application employed by the comparator or in accordance with the nature of the environment in which the comparator is to be used (e.g., a noisy or a noise-free environment). However, conventional methods and systems do not provide efficient means to digitally program the hysteresis width of a comparator.

### SUMMARY

In accordance with the teachings of the present disclosure, the disadvantages and problems associated with implementing hysteresis in a comparator have been substantially reduced or eliminated. In a particular embodiment, a system for implementing digitally programmable hysteresis in a comparator includes a digitally programmable variable resistor wherein modification of the resistance of the variable resistor is operable to modify the hysteresis width of the comparator.

In accordance with one embodiment of the present disclosure, a digitally programmable hysteresis comparator includes a digitally programmable variable resistor. One or more control bits are operable to modify the resistance of the variable resistor, and such modification is operable to modify the hysteresis width of the comparator.

In accordance with another embodiment of the present disclosure, an integrated circuit includes a digitally programmable hysteresis comparator. The digitally programmable hysteresis comparator includes a digitally programmable variable resistor. One or more control bits are operable to modify the resistance of the variable resistor, and such modification is operable to modify the hysteresis width of the comparator.

In accordance with another embodiment of the present disclosure, a system for implementing digitally programmable hysteresis in a comparator includes a digitally programmable variable resistor. One or more control bits are operable to modify the resistance of the variable resistor, and such modification is operable to modify the hysteresis width of the comparator.

In accordance with another embodiment of the present disclosure, a method for implementing digitally programmable hysteresis in a comparator includes providing a digitally programmable variable resistor. The method further includes manipulating one or more control bits, such manipulation being operable to modify the resistance of the variable resistor, and such modification being operable to modify the hysteresis width of, the comparator.

### BRIEF DESCRIPTION OF THE DRAWINGS

A more complete understanding of exemplary embodiments and advantages thereof may be acquired by referring to the following description taken in conjunction with the accompanying drawings, in which like reference numbers indicate like features, and wherein:

FIG. 1 illustrates an ideal voltage comparator, as is known in the art;

FIG. 2 illustrates a voltage transfer curve (VTC) for the ideal voltage comparator depicted in FIG. 1;

FIG. 3 illustrates a hysteresis comparator circuit, as is known in the art;

FIG. 4 illustrates a VTC for the hysteresis comparator circuit depicted in FIG. 3;

FIG. 5a illustrates sample waveforms for the input voltage and output voltage versus time for the ideal voltage comparator depicted in FIG. 1;

FIG. 5b illustrates sample waveforms for the input voltage and output voltage versus time for the hysteresis comparator circuit depicted in FIG. 3;

FIG. 6 illustrates an embodiment of a digitally programmable hysteresis comparator circuit, in accordance with teachings of the present disclosure;

FIG. 7 illustrates an embodiment of a digitally programmable variable resistor used in implementing a digitally programmable hysteresis comparator circuit, in accordance with teachings of the present disclosure; and

FIG. 8 illustrates a truth table setting forth the values of resistance for the digitally programmable variable resistor depicted in FIG. 7 based on different input values, in accordance with teachings of the present disclosure.

### DETAILED DESCRIPTION

Preferred embodiments and their advantages are best understood by reference to FIGS. 6 through 8, wherein like numbers are used to indicate like and corresponding parts.

For the purposes or this disclosure, comparators (or “voltage comparators”) may include any circuit component or device capable of comparing at least one signal or value received at an input, such as a voltage, against one or more other signal or value received at one or more other inputs, such as a voltage, and output one or more discrete signals or values, such as a voltage, based on the relative strengths, intensities, amplitudes or values of the input signals. Comparators may be used in various phases of signal generation and transmission, as well as in automatic control and measurement to implement any number of applications within microprocessors, microcontrollers, integrated circuits and other electronic components and circuits. Comparators are used alone or as part of larger systems, such as analog-to-digital converters, switching regulators, function generators, voltage-to-frequency converters, power-supply supervisors, level detectors, window detectors, pulse-width modulators, Schmitt triggers, and a variety of others.

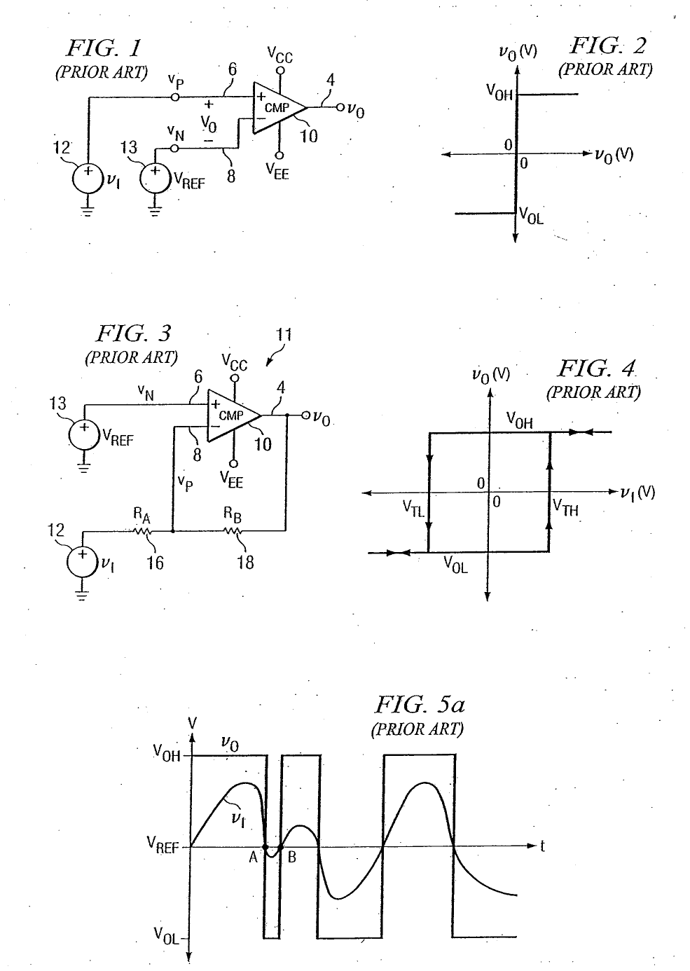

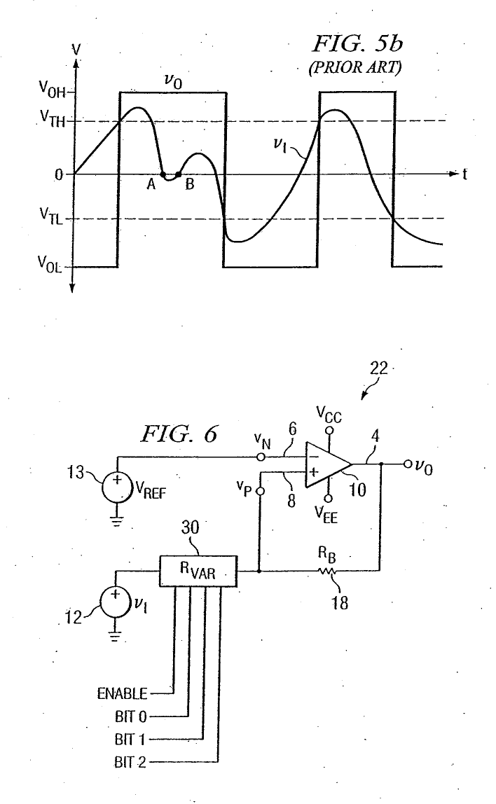

FIG. 6 illustrates a digitally programmable hysteresis comparator circuit 22. Although a specific circuit topology is illustrated in FIG. 6, it is understood that comparator circuit 22 may include any number of suitable circuit designs, layouts, or topologies for implementing a hysteresis comparator circuit. In the illustrated embodiment, comparator circuit 22 may include ideal voltage comparator 10, with ideal inputs 6 and 8 and output 4, similar to the ideal voltage comparator depicted in FIG. 1. In addition, comparator circuit 22 may include voltage source 12, which supplies a voltage v_{I}, and voltage source 13, which supplies a voltage V_{REF}. Although depicted as independent voltage sources, voltage sources 12 and 13 may be any voltage signals suitable for being input to a comparator circuit. Either or both of voltage sources 12 and 13 may be an electrical signal transduced by a temperature sensor, pressure sensor, strain sensor, position sensor, fluidic level sensor, light or sound intensity sensor, or other suitable sensor. In some embodiments, either or both of voltage sources 12 and 13 may correspond to a control signal, such as desired temperature for a thermostat, or some other critical or threshold measure in a level-detection circuit. In some embodiments, voltage sources 12 and 13 may be analog signals that are to be converted to a digital signal by one or more comparator circuits analogous to comparator circuit 22.

Comparator circuit 22 may also include one or more biasing elements used to establish the hysteresis width of comparator circuit 22, such as resistor 18 with fixed resistance R_{B} and digitally programmable variable resistor 30 with variable resistance R_{VAR}. Although FIG. 6 depicts that resistor 30 has a variable resistance and resistor 18 has a fixed resistance, it is understood that other topologies may be employed. For example, in some embodiments, comparator circuit 22 may be modified such that the locations of resistor 18 and resistor 30 are swapped. In other embodiments, both of resistor 18 and resistor 30 may be digitally programmable variable resistors. In addition, although comparator circuit 22 is depicted as comprising resistor 18 and digitally programmable variable resistor 30 as its only biasing elements, it is understood that comparator circuit 22 may include any number of fixed or variable biasing elements, including without limitation, resistors, capacitors, inductors, diodes, transistors, or any other passive or active circuit components.

In the depicted embodiment, the hysteresis width of comparator circuit 22 may be expressed as:

$$Δ {V}_{T} = \frac{{R}_{VAR}}{{R}_{B}} ( {V}_{OH} - {V}_{OL} )$$

where ΔV_{T} represents the hysteresis width, V_{OH} represents the maximum output voltage of comparator circuit 22 and V_{OL} represents the minimum output voltage of comparator circuit 22. Hence, in the depicted embodiment, one may vary the hysteresis width of comparator circuit 22 by varying the resistance R_{VAR} of digitally programmable variable resistor 30.

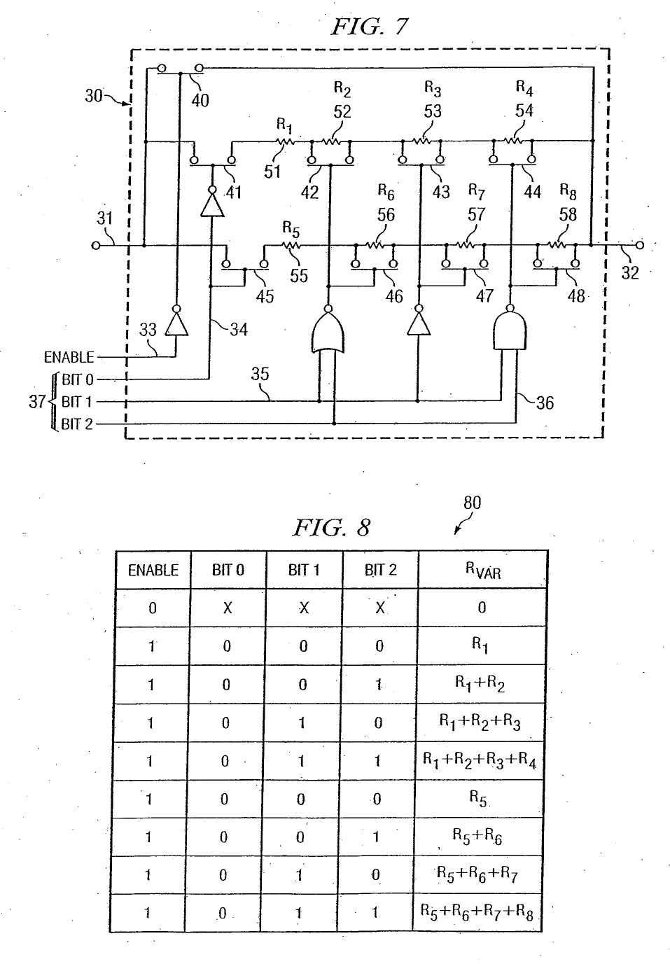

FIG. 7 illustrates an embodiment of a digitally programmable variable resistor 30 used for implementing digitally programmable hysteresis comparator circuit 22. Although a specific circuit topology is illustrated in FIG. 7, it is understood that variable resistor 30 may include any number of suitable circuit designs, layouts, or topologies for implementing a variable resistor similar or analogous to that set forth in this disclosure.

In the illustrated embodiment, variable resistor includes terminals 31 and 32. Variable resistor 30 as depicted also includes an enable bit 33, allowing the user to selectively enable variable resistor 30. Variable resistor 30 as shown further includes one or more control bits, such as control bits 34, 35, and 36 representing BIT0, BIT1 and BIT2 of a digital control signal 37, respectively, as shown in the depicted embodiment.

Variable resistor 30 also includes one or more resistors 51-58 with resistance values of R₁, R₂, R₃, R₄, R₅, R₆, R₇ and R₈, respectively, and switches 40-48 operable to enable or disable variable resistor 30 or to enable or disable individual resistors 51-58. Switches 40-48 may be any circuit component capable of making or breaking an electrical circuit, or for selecting between multiple circuits. As depicted in FIG. 7, variable resistor 30 may include a first set of series resistors 51-54, and a second set of series resistors 55-58 in parallel with the first set. One of the control bits 37, for example BIT 0 as shown in FIG. 7, may enable the first set of series resistors and disable the second set of series resistors, or vice versa. A remainder of the control bits 37 may then control selective bypassing of one or more of the resistors in the enabled set of series resistors.

The operation of digitally programmable variable resistor 30 may be described with reference to truth table 80 depicted in FIG. 8. Truth table 80 sets forth the values of resistance R_{VAR} between terminals 31 and 32 of digitally programmable variable resistor 30 based on whether the variable resistor has been enabled via enable bit 33 and the input values of the digital control signal represented by BIT0, BIT1 and BIT2 on control bits 34, 35 and 36.

In many applications, it may be desirable for a use to disable hysteresis in comparator circuit 22. Referring again to the equation for determining hysteresis width in comparator circuit 22:

$$Δ {V}_{T} = \frac{{R}_{VAR}}{{R}_{B}} ( {V}_{OH} - {V}_{OL} )$$

From the equation, it is evident that for R_{VAR}=0, ΔV_{T}=0, and no hysteresis is present in comparator circuit 22. In the depicted embodiment, this can be accomplished by appropriately setting the enable signal on input 33. Referring to the first row of truth table 80, when the enable signal on input 33 is set to 0, switch 40 is closed creating a conductive path between terminals 31 and 32, and the resistance R_{VAR} is equal to zero, meaning ΔV_{T}=0.

However, where it is desirable to include hysteresis in comparator circuit 22, the user may set the enable signal to the appropriate value (e.g., logic 1 in the depicted embodiment). When variable resistor 30 is enabled, control signals such as control signals BIT0, BIT1, and BIT2 may be used to control the resistance R_{VAR}, thus allowing the user to control hysteresis width. In the depicted embodiment, the user may selectively manipulate BIT0, BIT1, and BIT2 to set the resistance R_{VAR} to a desired value. For example, referring to the fourth row of values in truth table 80, enable bit 33 may be set to logic 1, BIT0 (control bit 34) to logic 0, BIT1 (control bit 35) to logic 1, and BIT2 (control bit 36) to logic 0. In such as case, switches 40, 42, 43 and 45 are open, switches 41 and 44 are closed, and a circuit path is completed between terminals 31 and 32 with a resistance R_{VAR}=R₁+R₂+R₃. It is evident from FIGS. 7 and 8 that numerous other values for R_{VAR} may be selected.

Although variable resistor 30 is depicted as utilizing three control bits operable to select among eight values for resistance R_{VAR} when enabled, it is understood that variable resistor may comprise any number N of control bits used to select any number 2^{N} of values for resistance R_{VAR}. Accordingly, although variable resistor 30 is depicted as utilizing nine switches and eight resistors, it is understood that variable resistor 30 may comprise an appropriate number of switches and resistors suitable to implement variable resistor 30 with N control bits and 2^{N} possible values of resistance.

Utilizing the methods and systems set forth in this disclosure, one may digitally program a hysteresis comparator to configure a desired hysteresis width. A comparator with digitally programmable hysteresis may be useful for many purposes. For example, digitally programmable hysteresis comparator may be useful to allow a user to fine tune hysteresis width appropriately to the particular application for which the comparator is used. In addition, a user may fine tune hysteresis width to an appropriate level based on the electrical noise present in a circuit.

Although the present disclosure as illustrated by the above embodiments has been described in detail, numerous variations will be apparent to one skilled in the art. It is understood that various changes, substitutions and alternations can be made herein without departing from the spirit and scope of the disclosure as illustrated by the following claims.

What is claimed is:

1. A digitally programmable hysteresis comparator, comprising:
a digitally programmable variable resistor; and
one or more control bits operable to modify the resistance of the variable resistor;
wherein the modification of the resistance of the variable resistor is operable to modify the hysteresis width of the comparator.

2. The comparator of claim 1, further comprising an enable bit operable to selectively enable the variable resistor.

3. The comparator of claim 2, wherein disabling the variable resistor produces a hysteresis width of approximately zero.

4. The comparator of claim 1, wherein the variable resistor includes a first set of series resistors and a second set of series resistors in parallel with the first set.

5. The comparator of claim 4, wherein a first of the control bits enable the first set of series resistors and disabled the second set.

6. The comparator of claim 5, wherein a remainder of the control bits control selective bypassing of at least some of the resistors in the enabled set of series resistors.

7. The comparator of claim 1 wherein the variable resistor is connected between an input terminal and a positive input of a voltage comparator.

8. The comparator of claim 1 wherein the variable resistor is connected between and output of a voltage comparator and a positive terminal of the voltage comparator.

9. The comparator of claim 8 further comprising a second variable resistor connected between an input terminal of the hysteresis comparator and the positive input terminal of the voltage comparator.

10. A system for implementing digitally programmable hysteresis in a comparator, comprising:
a digitally programmable variable resistor; and
one or more control bits operable to modify the resistance of the variable resistor;
wherein the modification of the resistance of the variable resistor is operable to modify the hysteresis width of the comparator.

11. The system of claim 10, further comprising an enable bit operable to selectively enable the variable resistor.

12. A method for implementing digitally programmable hysteresis in a comparator, comprising:
providing a digitally programmable variable resistor; and
manipulating one or more control bits, the manipulation operable to modify the resistance of the variable resistor;
wherein the modification of the resistance of the variable resistor is operable to modify the hysteresis width of the comparator.

13. The method of claim 12, further comprising manipulating an enable bit operable to selectively enable the variable resistor.
